(19) United States
(12) Patent Application Publication
(10) Pub. No.: US 2023/0403797 A1
(43) Pub. Date: Dec. 14, 2023

(54) Method for Filing at least One Hole formed in a Printed Circuit Board, a Printed Circuit Board filled in such a Manner, and a Vehicle Comprising such a Printed Circuit Board

(71) Applicant: ITC Intercircuit Electronic GmbH, München (DE)

(72) Inventor: Hubertus Hein, Bad Berka (DE)

(21) Appl. No.: 18/035,975

(22) PCT Filed: Nov. 9, 2021
(86) PCT No.: PCT/EP2021/081130

§ 371 Date: May 9, 2023

(30) Foreign Application Priority Data
Dec. 11, 2020 (DE) 10 2020 133 220.3

(51) Int. Cl. H05K 3/00; H05K 3/42; C25D 3/46; C25D 3/40; C25D 5/02

(52) U.S. Cl. CPC H05K 3/0094; H05K 3/427; C25D 3/46; C25D 3/40; C25D 5/022; H05K 2203/0723

(57) ABSTRACT

Disclosed are a method for filling at least one hole formed in a printed circuit board, a printed circuit board filled in such a manner, and a vehicle having such a printed circuit board. The method of filling at least one hole formed in a printed circuit board comprises: introducing a paste comprising an electrically conductive metal powder and an electrolyte into the at least one hole of the printed circuit board, S1; and galvanic metallization of the printed circuit board so that elemental metal is deposited from the electrolyte in the at least one hole during the galvanic metallisation, S2.

The present invention relates to a method of filling at least one hole formed in a printed circuit board, a printed circuit board filled in such a manner, and a vehicle comprising such a printed circuit board.

In the recent past, there has been a trend in the automotive industry away from common vehicles with combustion engines and towards electrically powered vehicles. The latter are vehicles with low-voltage drives. For this reason, there is an increasing need for printed circuit boards that can withstand also high current flows.

In this context, but also in general, the heat dissipation of certain components on the printed circuit board (PCB) is becoming increasingly important.

Usually, for applications in the field of high current flows, for example, so-called thick copper PCBs (where, for example, a copper layer up to 400 μm thick can be applied to the PCB) are used. In order to provide contacting between different layers, e.g., the two PCB surfaces (e.g., top side of the PCB and bottom side of the PCB) and/or in one of the inner conductive layers, holes (e.g., plated-through holes) can be formed in the PCB, for example. These can then be filled with electrically conductive material, which can also be thermally conductive, for example.

In general, different methods for filling holes in PCBs (and consequently different filling materials) are known.

One way of filling holes in PCBs, for example, is to completely fill a hole with conductive material by galvanic metallisation. This process can be used for small holes (e.g., holes with a small diameter), for example. However, apart from an increasingly long process time as the hole size increases, problems can arise with purely galvanic processes for PCBs with unfavourable ratios between the thickness of the PCB and the diameter of the hole. One problem can be, for example, that a hole closes galvanically at the end faces/axial end faces (for example at the hole opening(s)), while the space in between is/has not (been) or not sufficiently (been) galvanically filled with metal. This case can lead to defective through-hole plating.

In order to save metallic filling material and/or to shorten the duration of purely galvanic filling (for example, completely filling a hole by metallic galvanisation can take a very long time), resin-based fillings can presently be used, for example.

A corresponding method for filling holes formed in printed circuit boards may, for example, comprise the following steps:
(1) First, the printed circuit board, in particular the inner circumferential surface of a hole, is galvanically pre-metallised so that a sleeve-shaped metal layer is formed.
(2) A resin-based filler material, for example epoxy resin-based, is then introduced into the prepared hole, thereby filling or sealing the hole. This filling material may, for example, comprise conductive particles, for example conductive metal particles. In order to introduce the filling material into the hole, for example, a filling assembly can be used, such as disclosed in DE 10 2019 120 873 B3.

It is also known to cure a resin-based filling material after it has been filled in. This can be done, for example, by heating the filling material, especially in the case of an epoxy resin-based filling material. Additional sintering of the filler material (containing metal particles) may also be necessary at this point.

Finally, the PCB is again galvanically metallised, which coats the surface of the inserted resin plug, for example forming a so-called solder pad.

However, such resin-based fillings are very expensive, for example if they contain very small metal particles and/or contain complex metal particle systems. In addition, comparatively large resistances, low thermal conductivities and low peel strengths can occur, for example due to the use of resin.

The latter can be particularly important, for example, when the PCB is used in vehicles. In the case of high density interconnects (for example HDI circuits, for example High Density Interconnect circuits), which can be used, for example, in the field of high current applications with large and heavy electronic components and in which for example solder pads may be attached to the hole filling surfaces of the PCB, the adhesion of the solder pads (for example, the peel strength of the solder pads) to the filling of the hole is particularly important. Especially in vehicles, the adhesion of the solder pads can be heavily stressed due to the constant vibration loads, for example. For this reason, for example, a high peel strength of the solder pads on the hole filling surfaces in vehicles can be of great importance.

It may be considered an object of the present invention to provide an improved method for filling holes in printed circuit boards.

Alternatively or additionally, it may be considered an object of the present invention to provide an alternative method for filling holes in printed circuit boards.

Alternatively or additionally, it may be considered an object of the present invention to provide a low-cost method for filling holes in printed circuit boards.

Alternatively or additionally, it may be considered an object of the present invention to provide a method for rapidly filling holes in printed circuit boards.

Alternatively or additionally, it may be considered an object of the present invention to provide a method for filling holes in printed circuit boards which enables filling with low electrical resistance.

Alternatively or additionally, it may be considered an object of the present invention to provide a method for filling holes in printed circuit boards which enables filling with high thermal conductivity.

Alternatively or additionally, it may be considered an object of the present invention to provide a method for effectively and/or efficiently filling holes in printed circuit boards.

Alternatively or additionally, it may be considered an object of the present invention to provide a method for reliably filling holes in printed circuit boards.

Alternatively or additionally, it may be considered an object of the present invention to provide a method of filling holes in printed circuit boards which enables a stable filling.

Alternatively or additionally, it may be considered an object of the present invention to provide a universally applicable method for filling holes in printed circuit boards, for example with respect to differently formed/dimensioned holes.

Alternatively or additionally, it may be considered an object of the present invention to provide a method for filling holes in printed circuit boards which enables a filling with high peel strength compared to solder pads.

Furthermore, it may be considered an object of the present invention to provide a corresponding printed circuit board, as well as a vehicle comprising such a printed circuit board.

To this end, the present invention provides a method for filling at least one hole formed in a printed circuit board according to claim 1, a printed circuit board according to claim 13 and a vehicle according to claim 14. Further embodiments according to the invention are the subject of dependent claims 2 to 12.

According to various embodiments, the present invention relates to a hybrid process which combines advantages of the two filling processes mentioned at the beginning (“purely galvanic” and “resin paste”). Thereby, conductive material in the form of metal powder can be introduced into the hole via the paste, which reduces the time required for the galvanic process, wherein the electrolyte introduced with the paste (and possibly further electrolyte entering the filling from the electroplating bath) and the metal deposited therefrom bond the conductive material to each other and to the hole wall.

According to one aspect of the invention, a method for filling at least one hole formed in a printed circuit board may comprise, for example,
introducing a paste comprising an electrically conductive metal powder and an electrolyte into the at least one hole of the printed circuit board; and
galvanic metallisation of the printed circuit board so that elemental metal is deposited from the electrolyte in the at least one hole during the galvanic metallisation.

The printed circuit board may be, for example, a single-layer printed circuit board or a multilayer printed circuit board, which may comprise one or more inner conductive layers/tracks. The at least one hole may be, for example, a blind hole and/or a through hole. The at least one hole may be, for example, a drilled hole and/or a lasered hole. The printed circuit board may, for example, have a metal layer, for example copper layer, on its bottom and/or upper side. The insertion of the paste may happen, for example, manually and/or mechanically, for example, using a filling machine (also referred to as a plugging machine) of ITC Intercircuit Electronic GmbH, for example, a filling machine as described in DE 10 2019 120 873 B3. The paste comprises an electrically conductive metal powder and an electrolyte, and may for example consist of these two components, for example substantially. An optional further component of the paste may be, for example, a viscosity stabiliser as described further below. A mixing ratio of the electrically conductive metal powder and the electrolyte may be selected to adjust a suitable viscosity of the paste. In particular, in the case of machine processing, the paste may be provided and stored, for example, in a cartridge that can be inserted into the filling machine. The galvanic metallisation of the printed circuit board may, for example, be carried out in a separate process step subsequent to the filling step. For example, the galvanic metallisation of the printed circuit board may be performed in an electroplating bath. An electrolyte of the electroplating bath may, for example, comprise cations of the same chemical element/metal as the paste. For example, an electrolyte of the electroplating bath may also comprise anions of the same chemical element or the same chemical compound as the paste. For example, the electrolyte of the plating bath may be chemically the same as the electrolyte present in the paste, i.e. solvent, cations and anions may be chosen to be the same. In general, a cation concentration of the electrolyte in the paste may be, for example, higher (set) than that of the electroplating bath, for example, before/at the beginning of the metallic galvanisation and/or at a time when the PCB is introduced into the electroplating bath. This may favour, for example, a deposition of metal within the hole over a deposition of metal on another portion of the PCB, for example on the surface thereof. The cation concentration may be expressed, for example, in mol (cation number, e.g., copper ion number) per litre of solvent. The galvanic process may also be carried out, for example, with the so-called “pulse reverse plating” process (also called method for electroplating with reverse pulse current) and/or in an ultrasonic electroplating bath, in order to favour a uniform and rapid bonding between the introduced metal particles. During galvanic metallisation, metal is deposited from the electrolyte (of the paste) in the at least one hole. In addition, for example, metal from the (external) electrolyte (of the bath) may be deposited in the hole. In general, the deposition may take place, for example, in a direction radially inwards from the circumferential wall of the hole. During the galvanic metallisation, for example, other portions of the PCB, i.e. outside the hole, may also be galvanically metallised, for example an area above/below the hole and/or in top view around the hole. The deposited metal allows the conductive metal powder to bond well with each other and with the hole wall.

In the above process, it is not necessary to use a particularly fine-grained metal powder and/or a complex metal particle system. At the same time, the duration of the method may be significantly reduced compared to a purely galvanic process. Achievable material properties such as electrical conductivity, thermal conductivity and peel strength (for example, compared to a solder pad) are comparable to those that ideally result from the pure galvanic process (insofar as homogeneous overgrowth of the hole is achievable there). The solution according to the invention can be used universally, for example for large and small holes. The solidified (solid), galvanically bonded filling may also be stably attached in the hole. One or two (top and bottom) possible solder pads may be respectively formed in the galvanic step and stably bonded to the corresponding solid filling. In other words, the solder pad may be co-galvanically-metallised directly onto the hole filling, whereby comparatively high peel strength values are achievable, as the hole filling and solder pad bond well with each other (for example, better than in the case of a resin paste). The paste according to the invention may also be stored well, for example at room temperature, i.e., without the need for cooling.

According to one embodiment, in the method, for example, prior to the introduction of the paste (for example, in a separate preceding process step), an inner circumferential wall of the at least one hole may be galvanically pre-metallised to form a sleeve-like metal layer, wherein the paste is introduced into a space delimited by the sleeve-like metal layer. In other words, the hole or its peripheral wall may be pre-metallised. This makes it possible for the electric current to reach the respective hole well and over a large area during the subsequent galvanisation, right from the beginning, whereby a good, homogeneous on-growth can be achieved. The current density may grow slowly from the sleeve towards the centre of the hole, i.e., the hole filling can first be bonded to the sleeve by the galvanic and then gradually grow inwards. The layers bonded in this way become more electrically conductive and in this way favour a transformation from powder mixture to solid metal with the corresponding properties. For example, the sleeve-like metal layer may be bonded to a conductive portion of the PCB surface, which may be, for example, formed as an unstructured, closed copper layer. For example, the sleeve may grow from a conductive portion of a PCB surface towards and/or into the hole during pre-metallisation. For example, the sleeve may be a metal sleeve of the same metal as the cations in the paste, for example a copper sleeve in the case of copper cations in the paste. The pre-metallisation of the sleeve may be carried out, for example, in a corresponding pre-metallisation electroplating bath. An electrolyte of the pre-metallisation electroplating bath may, for example, comprise cations of the same chemical element/metal as the paste. For example, an electrolyte of the pre-metallisation electroplating bath may also comprise anions of the same chemical element/compound as the paste. For example, the electrolyte of the pre-metallisation electroplating bath may be chemically the same as the electrolyte in the paste, i.e., solvent, cations and anions may be chosen to be the same.

Additionally or alternatively, according to an embodiment example in the method, for example, the PCB exposed to the galvanic metallisation may be provided with a protective layer (for example a dry film) on the PCB bottom side and/or the PCB top side, which protects against deposition of metal during galvanic metallisation on a copper layer applied to the PCB bottom side and/or the PCB top side. In other words, by suitably masking the PCB bottom side and/or the PCB top side, for example, uncontrolled/undefined/undesired electrolytic epitaxial growth of metal can be avoided.

In addition or alternatively, according to one embodiment, the metal powder may, for example, have copper particles, silver particles and/or silver-plated copper particles, for example, consist of these. This allows good properties to be achieved at a reasonable cost. For example, pure copper particles and/or silver particles can be used, for example, with a purity of greater than or equal to 99 wt % (based on the total particle mass), or silver-plated copper particles with a pure (greater than or equal to 99 wt %) copper core. For example, only particles of one type can be used, for example only copper particles or only silver particles.

Additionally or alternatively, according to an embodiment example, the metal powder may for example have an average particle diameter of the metal powder of greater than or equal to 10 μm, for example 10 μm to 70 μm, for example 20 μm to 70 μm, for example 20 μm to 60 μm, for example 30 μm to 60 μm, for example 30 μm to 50 μm. The average particle diameter may be, for example, a number average equivalent spherical diameter (or, for example, a number average particle circumferential diameter), and may be determined, for example, by analysis of all the particles (alternatively, for example, 100 randomly selected particles) of the metal powder. For this purpose, an equivalent spherical diameter (or, e.g., a particle circumferential diameter) can be determined for each analysed particle, for example in an optical image, for example software-supported, and the diameter of the equivalent circular area (or, e.g., the circumference) is assumed to be the particle diameter of the respective particle, in order to subsequently form the numerical average value of all particles (sum of the diameters divided by analysed number of particles, for example 100) as average particle diameter.

The particles are not limited to a particular shape and can be, for example, dendritic or (substantially) spherical particles.

In addition or alternatively, according to an embodiment example, the paste may comprise, for example, 90 wt % or more of the metal powder (based on the total paste mass), for example 90 wt % to 99 wt %. In this way, for example, the above-mentioned effects (such as, among other things, a shortening of the time period) can be achieved in a particularly suitable manner and a viscosity/processability of the paste can be well adjusted.

Additionally or alternatively, according to one embodiment, the paste electrolyte may, for example, comprise a solvent and cations dissolved in the solvent (for example, copper cations and/or silver cations), wherein the cations correspond to a metal of the metal powder. For example, only cations of one type may be used, for example only copper cations or only silver cations. For example, the electrolyte may comprise copper cations if the metal powder is a copper powder. Additionally or alternatively, the electrolyte may comprise, for example, silver cations when the metal powder is a silver powder. Additionally or alternatively, the electrolyte may, for example, comprise silver cations if the metal powder is a silver-coated copper powder. For example, the solvent may be fully or substantially (see, for example, also below) saturated in cations (for example, at room temperature, for example 25° Celcius, and/or ambient pressure, for example 101 325 Pa), or the electrolyte may be a saturated solution.

Additionally or alternatively, according to an embodiment example, the paste electrolyte may contain CuCN, CuSO₄, Cu[BF₄]₂, Cu(SO₃NH₂)₂, Cu₂[P₂O₇], AgCN, K[Ag(CN)₂] or a mixture of at least two components thereof dissolved in a suitable solvent, for example in aqueous solution, and/or the cations may originate from a salt dissolved in the solvent, for example an aqueous solution. The solvent may for example be or contain water, for example distilled water. The solvent may further comprise, for example, an acid, for example H₂SO₄, for example H₃PO₄, for example HNO₃, or a base, for example KOH, for example NaOH.

Additionally or alternatively, according to an embodiment example, the paste electrolyte may comprise, for example, a cation concentration that is greater (for example, at least 5% greater; for example, at least 10% greater; for example, at least 15% greater; for example, at least 20% greater; for example, at least 25% greater; for example, at least 30% greater; for example, at least 40% greater; for example, at least 50% greater) than a cation concentration of an electrolyte in an electroplating bath used for the galvanic metallisation. For example, the molar amount of the metal cations in one litre of solvent of the paste electrolyte may be greater than the molar amount of the metal cations in one litre of solvent of the electroplating bath electrolyte. The respective cation concentration or the respective molar amount of the metal cations can, for example, relate to a point in time to before/immediately at the beginning of the metallic galvanisation. The respective cation concentration may be considered, for example, at the same ambient temperature and/or ambient pressure. The higher cation concentration of the electrolyte in the paste compared to that of the electrolyte of the electroplating bath may, for example, favour a (targeted/controlled) deposition of solid/elemental metal from the electrolyte in the at least one hole compared to a deposition of solid/elemental metal on the PCB surface.

In addition or alternatively, according to an embodiment example, the paste can comprise 10 wt % or less of the electrolyte (based on the total paste mass), for example 1 wt % to 10 wt %. In this way, for example, the above-mentioned effects (by the appropriate provision of metallisable/reduceable cations) can be achieved in a particularly suitable manner and a viscosity/processability of the paste can be well adjusted. For example, the electrolyte may thereby be substantially saturated in dissolved cations, for example by having 80% or more of the maximum soluble cation molar amount present in the solution (for example at room temperature, for example 25° Celcius, and/or ambient pressure, for example 101 325 Pa), for example 85% or more, for example 90% or more, for example 95% or more, for example 99% or more.

Additionally or alternatively, according to one embodiment, the paste may further comprise, for example, one or more additives, for example a viscosity stabiliser.

Additionally or alternatively, according to an embodiment example, the paste can be free of an epoxy resin, for example free of epoxy resin, phenolic resin, polyamide resin and polyamide-imide resin, for example free of any resin binder. In this context, free can be understood to mean, for example, a mass fraction (based on the paste mass) of less than 1 mass % (mass fraction of epoxy resin or, if applicable, the sum of resins), for example less than or equal to 0.5 mass %, for example less than or equal to 0.1 mass %, and/or an active addition of epoxy resin, for example epoxy resin, phenolic resin, polyamide resin and polyamide-imide resin, for example any resin binder, can be dispensed with in the production of the paste.

According to another aspect of the invention, there is provided a printed circuit board produced by a method as described above, or a printed circuit board having at least one hole filled by a method as described above. Such a printed circuit board can be used in many fields of the technology, and it is understood that the invention is not limited to any particular use or application.

For example, according to yet another aspect of the invention, such a circuit board may be used in a vehicle (for example, land, air or water vehicle, for example, automobile or aircraft), for example, an electrically powered vehicle.

According to a further aspect of the invention, a vehicle (for example, a land, air or water vehicle, for example, an automobile or aircraft) having such a printed circuit board is accordingly further provided, which may be, for example, an electrically powered vehicle.

According to a still further aspect of the invention, there may further be provided a paste formed as described in connection with the above method.

According to a still further aspect of the invention, there may further be provided a cartridge in which such a paste is received and which is adapted, for example, for insertion into a filling machine.

According to a still further aspect of the invention, moreover, such a paste and/or cartridge may be used to fill one or more holes in a printed circuit board.

Exemplary but non-limiting embodiments of the invention are explained in more detail below.

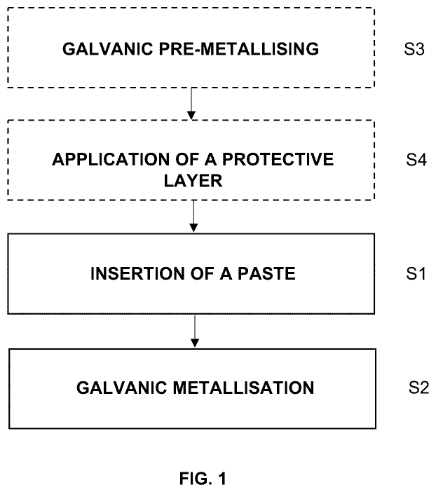

FIG. 1 shows a flowchart describing a method for filling at least one hole formed in a printed circuit board.

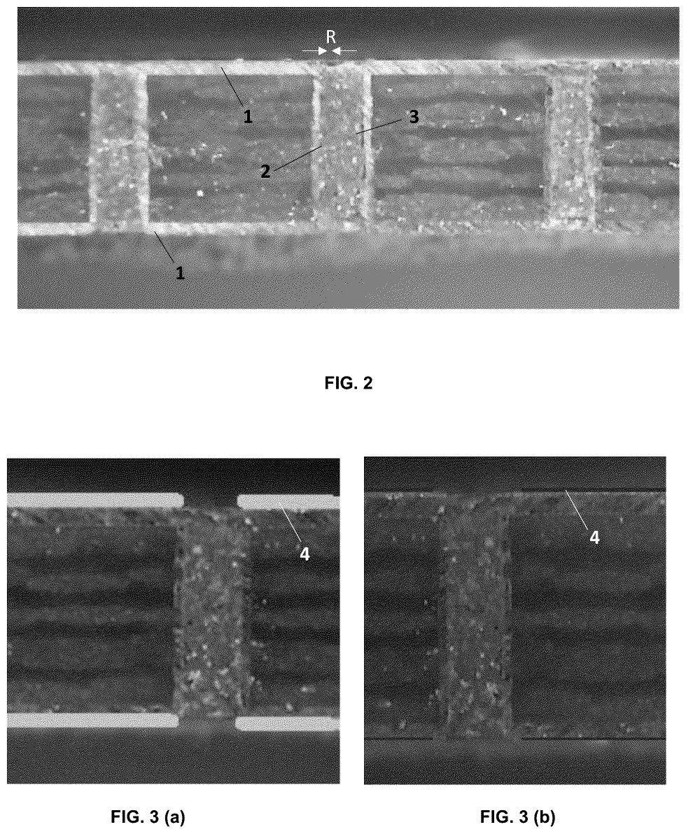

FIG. 2 shows a photograph of a cross-sectional view of a printed circuit board, the holes of which are filled with a solidified or galvanically converted/bonded, previously paste-like filling according to the present invention.

FIG. 3 (a) and FIG. 3 (b) each show a photograph of a cross-sectional view of a printed circuit board showing an applied optional protective layer.

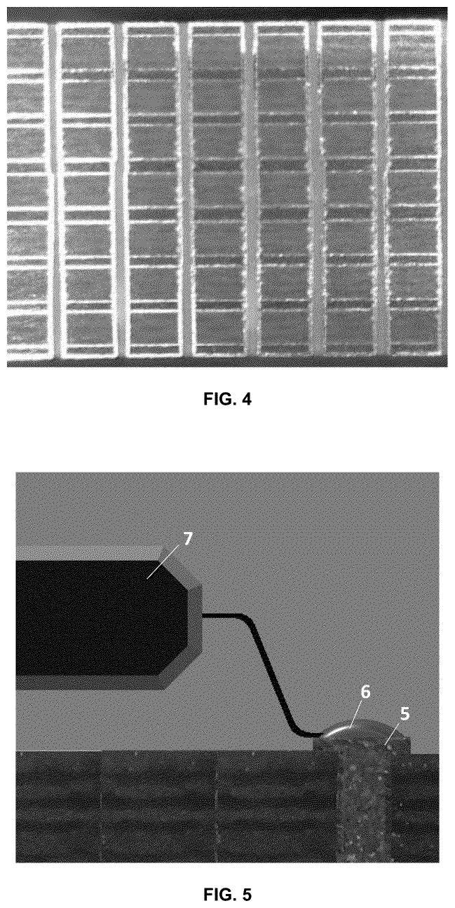

FIG. 4 shows a photograph of a cross-sectional view of a multilayer printed circuit board in which a plurality of holes are formed, each extending in the thickness direction of the printed circuit board across multiple/all layers.

FIG. 5 shows a photograph of a cross-sectional view of a printed circuit board showing a solder mounted on a solder pad that is electrically connected to an electronic component.

In the following description, reference is made to the accompanying figures which form part thereof and in which specific embodiments in which the invention may be practised are shown by way of illustration.

It is understood that other embodiments may be used and structural or logical changes may be made without departing from the scope of protection of the present invention. It is understood that the features of the embodiments described herein may be combined with each other, unless specifically stated otherwise. The following description is therefore not to be construed in a limiting sense, and the scope of protection of the present invention is defined by the appended claims.

FIG. 1 shows a flowchart describing a method for filling at least one hole formed in a printed circuit board. Referring now to FIG. 1, a method for filling at least one hole formed in a printed circuit board according to one embodiment of the invention is described.

First, for example, a paste comprising an electrically conductive metal powder and an electrolyte may be introduced into the at least one hole of the printed circuit board, step S1.

The printed circuit board can be, for example, a standard single-layer printed circuit board with two electrically conductive outer layers (for example, copper layers) or a multilayer printed circuit board. In this regard, FIG. 4 shows, by way of example, a photograph of a cross-sectional view of a multilayer printed circuit board in which several holes (in this case through-holes) are formed, each of which extends in the thickness direction of the printed circuit board across several/all layers.

The electrically conductive metal powder in the paste may comprise, for example, copper particles (in another embodiment, silver particles or silver-plated copper particles may be used, for example). An average particle diameter of the copper metal powder may be, for example, greater than or equal to 10 μm and may be, for example, in the range of 30 μm to 50 μm. The paste may comprise, for example, 90 wt % or more of the metal powder, for example 90 wt % to 99 wt %.

For example, the electrolyte may comprise a suitable solvent and cations dissolved in the solvent, in this case copper cations. For example, the electrolyte may contain CuCN or CuSO₄ dissolved in the solvent. Further, the electrolyte may be, for example, an aqueous solution. The cations may, for example, be derived from a salt dissolved in the solvent. The paste may comprise, for example, 10 wt % or less of the electrolyte, for example, 1 wt % to 10 wt %. The paste may further comprise, for example, an additive. The additive may be, for example, a viscosity stabiliser.

The paste may be free of an epoxy resin, for example, free of epoxy resin, phenolic resin, polyamide resin and polyamide-imide resin, for example, free of any resin binder.

Further with reference to FIG. 1, after the paste is introduced into the at least one hole of the printed circuit board, S1, for example, av galvanic metallisation of the printed circuit board, S2, may be performed. Thereby, for example, during the galvanic metallisation, S2, elemental metal may be deposited from the electrolyte in the at least one hole.

Thus, for example, the deposited elemental metal can bond with the particles of the metal powder and altogether form a cohesive (for example, one-piece), solid, thermally and electrically conductive metal filling 2 in the at least one hole of the printed circuit board. In this respect, FIG. 2 shows by way of example a solidified/galvanically bonded metal filling 2 according to one embodiment of the present invention.

The paste electrolyte may, for example, comprise a cation concentration that is greater than a cation concentration of an electroplating bath or its electrolyte in which the galvanic metallisation is carried out (for example, by immersing the PCB in it), in order to specifically promote metallisation in the hole.

According to an exemplary aspect of the present invention, prior to the introduction of the paste, S1, for example, an inner peripheral wall of the at least one hole may optionally be pre-metallised by electroplating to form a sleeve-like metal layer 3, S3. The paste may then be introduced, for example, into a space delimited by the sleeve-like metal layer 3, S1. An example of such a sleeve-like metal layer 3 is shown in FIG. 2. The sleeve-like metal layer 3 may thus be an electrolytically deposited metal sleeve of, for example, the same metal as that of the paste metal powder and the paste cations.

The formation of the sleeve-like metal layer 3 may, for example, allow the current density to grow in a controlled/defined manner over the axial extent of the hole in the direction R (cf. FIG. 2) from the sleeve-like metal layer 3 on the inner circumferential wall of the at least one hole towards a centre of the at least one hole during the galvanic metallisation, S2. For example, the filling may first be connected to the sleeve-like metal layer 3. Fillings produced in this way may, for example, have particularly good properties, such as electrical conductivity. However, the method according to the invention or the metallisation/solidification of the filling can also be carried out without galvanic pre-metallisation, S3.

According to another exemplary aspect of the present invention, the printed circuit board subjected to galvanic metallisation may be provided with a protective layer 4, S4, for example on the PCB bottom side and/or the PCB top side. In this regard, FIG. 3 (a) and FIG. 3 (b) each show a photograph of a cross-sectional view of a printed circuit board showing an applied optional protective layer 4. The protective layer 4 may, for example, protect against deposition of metal during the galvanic metallisation S4 on a copper layer 1 (e.g., thick copper layer) applied to the PCB bottom side and/or PCB top side. For example, a conventionally used dry film can serve as a protective layer 4.

As shown in FIG. 1, the application of the protective layer, S4, may be performed, for example, before the paste is introduced into the printed circuit board, S1. Alternatively, the application of the protective layer, S4, may be carried out, for example, after the introduction of the paste, S1, into the printed circuit board. The sequence of steps S3 and S4 shown, if both are carried out, can also be reversed.

A printed circuit board made by the method for filling at least one hole formed in a printed circuit board according to the present invention may be used, for example, in a vehicle. A vehicle may be, for example, a land vehicle, aircraft or watercraft.

FIG. 5 shows a photograph of a cross-sectional view of a printed circuit board according to the invention, showing a solder 6 attached to a solder pad 5, which is electrically connected to an electronic component 7. The solder pad 5 may be, for example, a patterned portion of the copper layer 1 on the PCB surface, including an area disposed over the hole and (re)sealed by the galvanic metallisation. Such an arrangement may be of great relevance, for example, in high density interconnect circuits (for example, HDI circuits, for example, “high density interconnect” circuits), which may be used, for example, in the field of high current applications with large and heavy electronic components 7. Especially in vehicles, an adhesion (e.g., peel strength) of the solder pad may be highly stressed due to the constant vibration loads, for example. For this reason, for example, a high peel strength of the solder pad 5 at the filling of the hole or on the hole filling surfaces in vehicles can be of great importance.

### Trial Examples

In accordance with the present invention, initial tests have been carried out.

First, approx. 95 wt % copper powder (manufacturer's data: electrolytically produced, dendritic 99.70% copper powder, oxygen: max. 0.3% (during production); bulk density: 1.8 g/cm³; 38 μm, 400 mesh, particle size distribution IS04497>106 μm: 0%, particle size distribution IS04497>63 μm: max. 5.0%, particle size distribution IS04497>45 μm: max. 10.0%; Werth metal) and approx. 5 wt % of an acidic CuSO₄ electrolyte solution (Glanzkupferelektrolyt sauer from MARAWE GmbH & Co. KG, Art. No. 01-10-01000) were mixed in a beaker. The electrolyte solution was added gradually, drop by drop towards the end, and the mixture was stirred with a copper spatula for a longer time until the copper particles were well wetted with the electrolyte solution and a paste had formed. Using a doctor blade, the paste was then introduced into the through holes of a printed circuit board.

The PCB was then subjected to electrolysis. For this, the PCB was placed in an electroplating bath. The electrolyte solution of the electroplating bath was the same electrolyte solution that was used to mix with the copper particles and to make the paste. Furthermore, the printed circuit board was connected at its thick copper layer 1 as cathode. A copper plate, which was also in the electroplating bath, served as the anode.

These procedures/experimental set-up were/was repeated for the various experiments described below.

Different voltages were then applied in different experiments. The series of experiments was started with 3 V in the first experiment and the voltage was reduced to 1 V in the last experiment. The best results were observed for a voltage of 1 V in the present experimental setup. However, it must be expected that the voltage must be adjusted depending on the thickness of the PCB, the diameter of the holes and other influencing factors.

Furthermore, the duration of the electrolysis was varied in different experiments. In particular, different electrolysis durations from 30 to 60 minutes were investigated. It was found that in the present experimental set-up, a solid copper filling could be observed already from an electrolysis duration of 30 minutes. The circuit board produced could be ground down and showed a hole well and evenly filled with copper when viewed under the microscope.

Furthermore, tests were carried out in which the paste was introduced into galvanically pre-metallised holes (where the inner circumference of a hole had a sleeve-shaped metal layer 3) or metal-free holes (where the inner circumference of a hole had no sleeve-shaped metal layer 3, for example). In both cases, successful through-connection was observed. However, in the tests in which the holes were galvanically pre-metallised, it was found that a more uniform filling had formed in the holes.

The tests performed so far have been carried out without applying a dry film as a protective layer 4 on the PCB surfaces. However, the use of a dry film can be considered to avoid an on-growth of electrolytic metal on, for example, the top and/or bottom of the board and/or, for example, when using silver pastes (for example, in galvanic silver plating) to avoid a deposition of silver on the copper layer.

The experiments carried out so far were also carried out with a paste electrolyte cation concentration that was equal to the cation concentration of the electrolyte in the electroplating bath. By diluting the electrolyte in the electroplating bath, the cation concentration of the electrolyte in the electroplating bath can be easily adjusted to a lower value than the paste electrolyte cation concentration. Alternatively or additionally, a paste electrolyte cation concentration can be increased by adding an appropriate metal salt into the electrolyte of the paste (for example, before mixing with metal powder), and/or a separate, higher concentrated electrolyte can be used.

The galvanolysis can also be carried out, for example, with a reverse pulse current method for electroplating and/or in a galvanic ultrasonic bath. This is expected to produce a uniform and rapid bonding between the introduced copper particles.

Initial measurement results show that the fillings of holes in printed circuit boards produced in this way are superior to conventional paste fillings (in particular, resin-based pastes, especially epoxy-based pastes) in terms of electrical conductivity and thermal conductivity. Furthermore, the filling produced according to the present invention is expected to have a high peel strength compared to that of resin-bonded (e.g., epoxy-bonded) metal pastes, and the paste according to the invention is easy to store.

Furthermore, the measured properties are comparable to those of purely galvanic metal fillings of holes in PCBs. However, the latter are not universally applicable (for example, for all types of holes in PCBs), and purely galvanic filling of holes can sometimes take a very long time (for example, several days compared to less than 60 minutes for the method according to the present invention).

1. A method for filling at least one hole formed in a printed circuit board, the method comprising:
introducing a paste comprising an electrically conductive metal powder and an electrolyte into the at least one hole of the printed circuit board; and
galvanic metallisation of the printed circuit board so that elemental metal is deposited from the electrolyte in the at least one hole during the galvanic metallisation.

2. The method according to claim 1, wherein prior to the introduction of the paste (S1), an inner peripheral wall of the at least one hole galvanically pre-metallised to form a sleeve-like metal layer and the paste is introduced into a space delimited by the sleeve-like metal layer.

3. The method according to claim 1, wherein the printed circuit board exposed to galvanic metallisation is provided with a protective layer on the printed circuit board bottom side and/or the printed circuit board top side which protects against deposition of metal during galvanic metallisation on a copper layer applied to the printed circuit board bottom side and/or the printed circuit board top side.

4. The method according to claim 1, wherein the metal powder comprises copper particles, silver particles and/or silver-plated copper particles.

5. The method according to claim 1, wherein an average particle diameter of the metal powder is greater than or equal to 10 μm.

6. The method according to claim 5, wherein the paste comprises 90 wt % or more of the metal powder.

7. The method according to claim 6, wherein the electrolyte comprises a solvent and cations dissolved in the solvent, the cations corresponding to a metal of the metal powder.

8. The method according to claim 7, wherein the electrolyte comprises CuCN, CuSO₄, Cu[BF₄]₂, Cu(SO₃ NH₂)₂, Cu[P₂O₇], AgCN, K[Ag(CN)₂] or a mixture of at least two components thereof dissolved in the solvent and/or wherein the cations originate from a salt dissolved in the solvent.

9. The method according to claim 1, wherein the electrolyte has a cation concentration greater than a cation concentration of an electrolyte in an electroplating bath of the galvanic metallisation.

10. The method according to claim 1, wherein the paste comprises 10 wt % or less of the electrolyte.

11. The method according to claim 1, wherein the paste further comprises an additive.

12. The method according to claim 1, wherein the paste is free of an epoxy resin phenolic resin, polyamide resin.

13. A printed circuit board manufactured according to claim 1.

14. A vehicle comprising a printed circuit board according to claim 13.

15. The method according to claim 1, wherein the paste comprises 90 wt % or more of the metal powder.

16. The method according to claim 15, wherein the electrolyte comprises a solvent and cations dissolved in the solvent, the cations corresponding to a metal of the metal powder.

17. The method according to claim 16, wherein the electrolyte comprises CuCN, CuSO₄, Cu[BF₄]₂, Cu(SO₃ NH₂)₂, Cu[P₂O₇], AgCN, K[Ag(CN)₂] or a mixture of at least two components thereof dissolved in the solvent and/or wherein the cations originate from a salt dissolved in the solvent.

18. The method according to claim 1, wherein the paste further comprises a viscosity stabiliser.
